(19) United States
(12) Patent Application Publication
(10) Pub. No.: US 2018/0303002 A1
(43) Pub. Date: Oct. 18, 2018

(54) ELECTRONIC DEVICE FOR ELECTRICAL SOCKET

(71) Applicant: SHENG-HSIN LIAO, NEW TAIPEI CITY (TW)

(72) Inventor: SHENG-HSIN LIAO, NEW TAIPEI CITY (TW)

(21) Appl. No.: 15/849,554

(22) Filed: Dec. 20, 2017

(30) Foreign Application Priority Data
Apr. 13, 2017 (TW) 106205139

(51) Int. Cl. H05K 7/14; H01R 4/48; H01R 13/66

(52) U.S. Cl. CPC H05K 7/1417; H01R 13/665; H01R 4/4809

(57) ABSTRACT

An electronic device assembled in an electrical socket is provided. The electrical socket has plug holes and two conductive parts. The electronic device includes a supporting frame, a circuit unit disposed in the supporting frame and a panel board. The supporting frame has a first opening sleeved around the electrical socket. The two conductive elements are electrically connected to the circuit unit, and respectively have a contact portion. The two contact portions are disposed at two sides of the first opening of the supporting frame, and are contacted with the conductive parts of the electrical socket. The circuit unit is electrically connected to the electrical socket. The panel board covers on the supporting frame and has a second opening corresponding to the plug holes of the electrical socket. The plug holes of the electrical socket are exposed by the first opening and the second opening.

### BACKGROUND OF THE INVENTION

### 1. Field of the Invention

The present invention is related to an electronic device for an electrical socket, and in particular, to an electronic device being assembled in the electrical socket.

### 2. Description of Related Art

The current indoor electric power supply mostly is embedded in walls. Electrical sockets are mounted on the wall and conducted to the electric power supply or network signal. When an electronic product, such as a cellphone, a digital camera, a PDA device or other portable device, consumes the electricity power and needs to be charged to maintain its operation, supply the electricity or transmit information, user can put a plug in the electrical socket by connecting the network signal. Thus, the electronic product can connect the electric supply or network signal through a transmitting cable, to receive electricity power or network signal.

However, if an additional electronic device, such as a nightlight, a wireless charger or an emergency lighting, wants to connect to the electrical socket, the plug holes of the electrical socket will be occupied. It is hard to avoid occupying the limited-number plug holes on the electrical socket. Although some electronic device can be mounted on an original position of the electrical socket, the original electrical socket is necessary to be removed and it is not used.

The abovementioned drawbacks of the conventional electrical socket seem to suggest that there is still room for improvement in the art.

### SUMMARY OF THE INVENTION

One objective of the present disclosure is to provide an electronic device which is assembled in an electrical socket, so that the original electrical socket needs not to be removed, and the plug holes of the electrical socket are not occupied.

In order to achieve the above objectives, the present disclosure provides an electronic device for being assembled in an electronic device. The electrical socket has a plurality of plug holes formed on a front side thereof and two conductive parts. The two conductive parts are disposed at two sides of the electrical socket. The electronic device includes a supporting frame, a circuit unit, two conductive elements and a panel board. The supporting frame has a receiving space formed therein, and a first opening. The first opening is formed through a front side and a rear side of the supporting frame. The first opening of the supporting frame is fitted around a pheriphry of the electrical socket. The circuit unit is disposed in the receiving space of the supporting frame. The conductive elements, electrically connected to the circuit unit. Each of the conductive elements has a contact portion. The contact portions of the two conductive elements are arranged at two sides of the first opening of the supporting frame. the contact portions are protruded to a rear side of the supporting frame, and the contact portions of the two conductive elements are contacted to the two conductive parts of the electrical socket, so that the circuit unit is electrically connected to the electrical socket. The panel board has a second opening formed through a front side and a rear side of the panel board. The panel board covers on a front side of the supporting frame. The second opening of the panel board is arranged corresponding to the plug holes of the electrical socket, so that the plug holes of the electrical socket are exposed exteriorly by the first opening of the supporting frame and the second opening of the panel board.

Thus, the present disclosure has advantages as follows. By the present disclosure, the circuit unit of the electronic device has two conductive elements, and two contact portions of the conductive element are conducted with two conductive parts of the electrical socket, so that the circuit unit of the electronic device can be electrically connected to the electrical socket. The plug holes of the electrical socket are exposed exteriorly from the first opening of the supporting frame and the second opening of the panel board, so that the plug holes of the electrical socket still can be work normally. The electronic device of this present disclosure can be assembled easily, and the original electrical socket needn't to be removed, the plug holes of the electrical socket are not occupied.

For further understanding of the present disclosure, reference is made to the following detailed description illustrating the embodiments and examples of the present disclosure. The description is for illustrative purpose only and is not intended to limit the scope of the claim.

### BRIEF DESCRIPTION OF THE DRAWINGS

FIG. 1 is an exploded perspective view of an electronic device according to a first embodiment of the present disclosure;

FIG. 2 is another exploded perspective view of the electronic device according to the first embodiment of the present disclosure;

FIG. 3 is an assembled perspective view of the electronic device according to the first embodiment of the present disclosure;

FIG. 4 is an exploded perspective view of the electronic device according to a second embodiment of the present disclosure;

FIG. 5 is an exploded perspective view of the electronic device according to a third embodiment of the present disclosure;

FIG. 6 is another exploded perspective view of the electronic device according to the third embodiment of the present disclosure;

FIG. 7 is an assembled perspective view of the electronic device according to the third embodiment of the present disclosure;

FIG. 8 is an exploded perspective view of the electronic device according to a fourth embodiment of the present disclosure; and

FIG. 9 is an assembled perspective view of the electronic device according to a fifth embodiment of the present disclosure;

FIG. 10 is an exploded perspective view of the electronic device according to a sixth embodiment of the present disclosure;

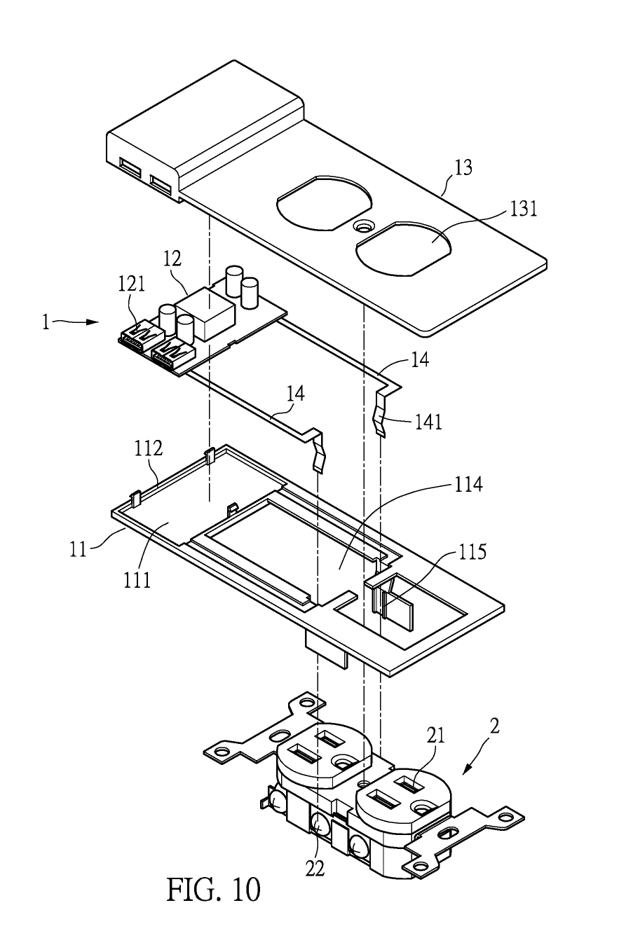

FIG. 11 is an assembled perspective view of the electronic device according to a seventh embodiment of the present disclosure; and

FIG. 12 is an assembled perspective view of the electronic device according to an eighth embodiment of the present disclosure.

### DETAILED DESCRIPTION OF THE EXEMPLARY EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings.

### First Embodiment

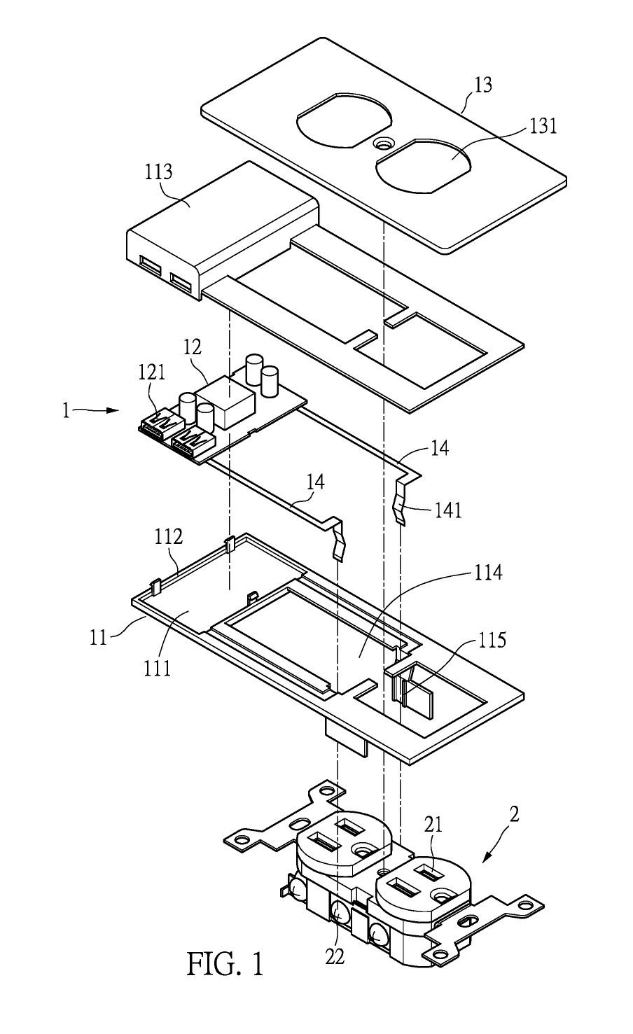

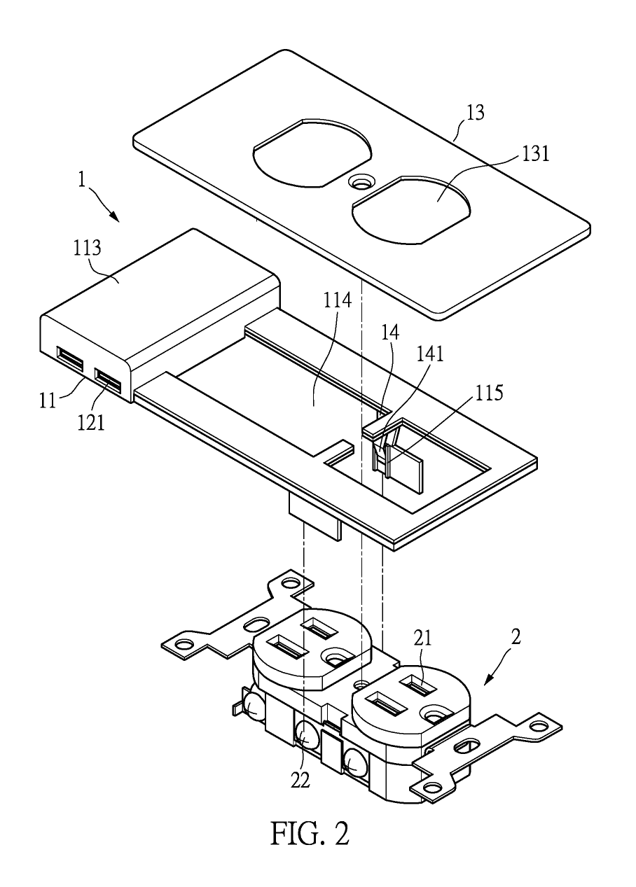

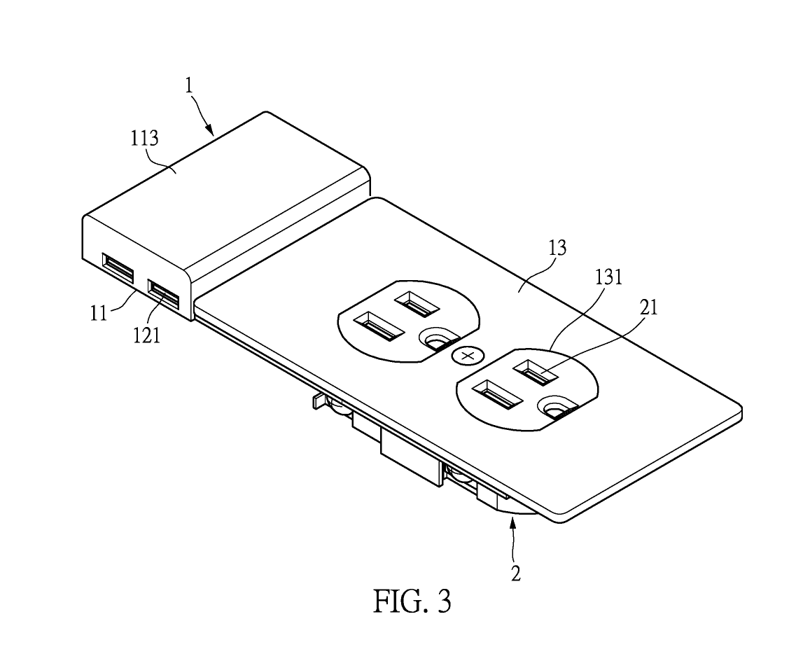

Reference is made to FIG. 1 to FIG. 3, the present disclosure provides an electronic device which is assembled in an electrical socket. The electronic device 1 is installed to an electrical socket 2, and the electronic device 1 is capable to electrically connect with the electrical socket 2. The electrical socket 2 has a plurality of plug holes 21 which is provided on a top side thereof. The quantity and type of plug hole 21 is not limited thereto. The electrical socket 2 has two conductive parts 22, which are disposed at two sides of the electrical socket 2. The two conductive parts 22 are electrically connected to conductive plates (not shown) in the plug hole 21. The electrical socket 2 can be an available electrical socket, which is not emphasized in the present disclosure, and is not reiterated herein for the sake of brevity.

The electronic device 1 includes a supporting frame 11, a circuit unit 12 and a panel board 13. The supporting frame 11 is a hollow shell, which can be shaped in a framework or U-configuration. The supporting frame 11 has a receiving space 111 formed therein, which could be used to receive the circuit unit 12. The supporting frame 11 can be one-piece or multiple-pieces structure. In this embodiment, the supporting frame 11 is a multiple-pieces structure, which includes a rear frame 112 and a front frame 113. The rear frame 112 and the front frame 113 are shaped in a framework or U-configuration, and could match to each other. The assembling manners of the rear frame 112 and the front frame 113 can be wedge, screw or attachment manners . . . etc. The receiving space 111 is formed between the rear frame 112 and the front frame 113.

The supporting frame 11 has a first opening 114, which is formed through the supporting frame 11 from a front side thereof to a rear side thereof. The first opening 114 has a shape corresponded to that of the electrical socket 2, so that the first opening 114 of the supporting frame 11 can be sleeved around the electrical socket 2. That is, the electrical socket 2 can be matched in the first opening 114 of the supporting frame 11. In this embodiment, the first opening 114 of the supporting frame 11 is shaped in a square which is corresponded to a contour of the electrical socket 2.

The supporting frame 11 has two clipping tabs 115, which are disposed at two sides of the first opening 114. The two clipping tabs 115 are extended rearward and protruded beyond a rear side of the supporting frame 11. The clipping tab 115 can be elastic tabs, so that the two clipping tabs 115 can be elastically clipped to two sides of the electrical socket 2. Thus, the electronic device 1 can be assembled with the electrical socket 2 firmly.

The type and structure of the circuit unit 12 is given an example as follows, but it is not limited thereto. The circuit unit 12 can be, for example, a transformer, a nightlight, a wireless charger, a security light, a wireless controller, a wireless access point (WAP), a wireless module, timer, a ground fault circuit interrupters (GFCI), a cord winder, sensor, a motion sensor or battery . . . etc. The circuit unit 12 is disposed in the receiving space 111 of the supporting frame 11. The circuit unit 12 is partially exposed outside the supporting frame 11. In this embodiment, the circuit unit 12 can be disposed above or under the supporting frame 11.

The circuit unit 12 is electrically connected with two conductive elements 14. The conductive elements 14 are made of conductive material, such as copper . . . etc. The conductive element 14 has one end electrically connected to the circuit unit 12, and the other end is formed with a contact portion 141. The contact portion 141 is extended rearward and protruded beyond the rear side of the supporting frame 11. The conductive elements 14 are disposed in the supporting frame 11. The assembling manner of the conductive element 14 and the supporting frame 11 can be wedge, screw, or attachment manners. The contact portions 141 of the two conductive elements 14 can be disposed at inner sides of the two clipping tabs 115. In other words, the two contact portions 141 of the conductive elements 14 can be arranged adjacent to two close sides of the clipping tabs 115. Two contact portions 141 of the conductive elements 14 can be wedged fixedly with the two clipping tabs 115. The contact portion 141 can be elastic tabs. The contact portions 141 of the two conductive elements 14 are disposed at two sides of the first opening 114 of the supporting frame 11. In addition, the contact portions 141 of the two conductive elements 14 are corresponding to the two conductive parts 22 of the electrical socket 2.

When the first opening 114 of the supporting frame 11 is sleeved around a periphery of the electrical socket 2, the contact portions 141 of the two conductive elements 14 can conduct electricity from the conductive parts 22 of the electrical socket 2. Thus, the circuit unit 12 is electrically connected with the electrical socket 2. In this embodiment, the circuit unit 12 has at least one electrical connector 121. The electrical connector 121 can be an USB connector, a IEEE1394 connector, a HDMI connector, an AV contact or the electrical connector with DC contacts. The electrical connector 121 is exposed outside the supporting frame 11, so that an electrical connector can be inserted to electrically connect with an electronic device.

The panel board 13 is a board, which is formed with a second opening 131. The numbers of the second opening 131 can be one or numerous. In this embodiment, there two second openings 131. The second openings 131 pass through the panel board 13 from a front side to a rear side. The panel board 13 covers at a front side of the supporting frame 11. The second openings 131 of the panel board 13 are corresponded with the plug holes 21 of the electrical socket 2, so that the plug holes 21 of the electrical socket 2 are exposed exteriorly from the first opening 114 of the supporting frame 11 and the second opening 131 of the panel board 13. Thus, a plug can be plugged into the plug holes 21 of the electrical socket 2. The panel board 13 can be fixed to the supporting frame 11 or the electrical socket 2 by a wedging or a screw manner.

According to the present disclosure, the circuit unit 12 of the electronic device 1 has two conductive elements 14, and the two contact portions 141 of the conductive elements 14 are conducted with two conductive parts 22 of the electrical socket 2, so that the circuit unit 12 of the electronic device 1 can be electrically connected to the electrical socket 2. The plug holes 21 of the electrical socket 2 are exposed exteriorly from the first opening 114 of the supporting frame 11 and the second opening 131 of the panel board 13, so that the plug holes 21 of the electrical socket 2 still can be work normally. The electronic device 1 of this present disclosure can be assembled easily, and the original electrical socket needn't to be removed, the plug holes of the electrical socket are not occupied.

### Second Embodiment

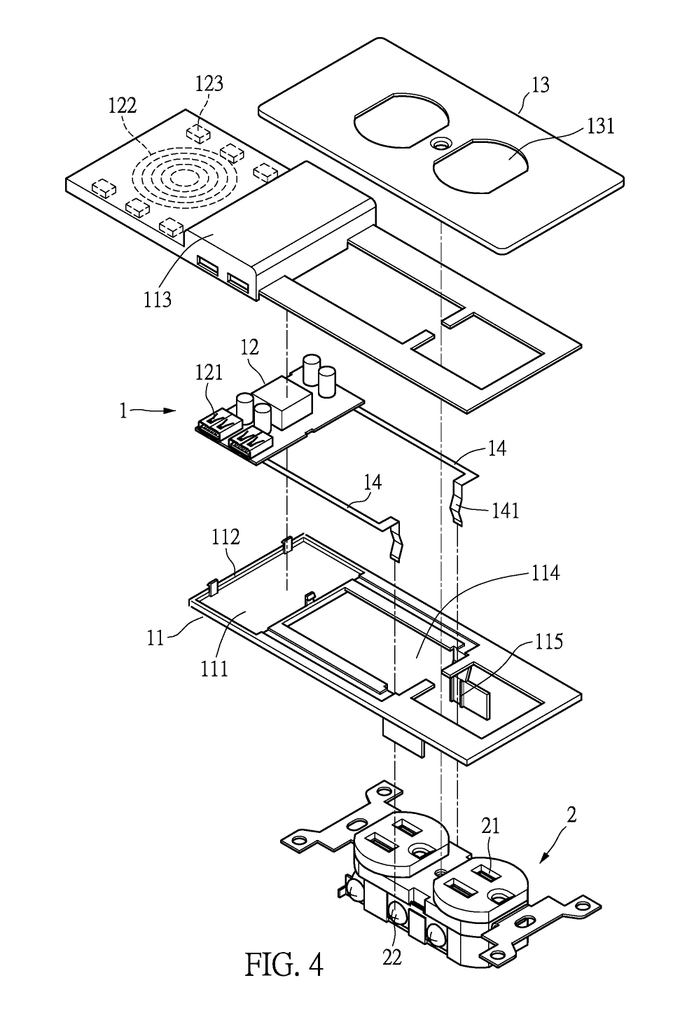

Reference is made to FIG. 4. In this embodiment, the electronic device 1 includes the supporting frame 11, the circuit unit 12 and the panel board 13. The structure of this embodiment is similar to the above embodiment, and a difference is that, the circuit unit 12 has a wireless charger 122. In addition, the circuit unit 12 could have a plurality of magnets 123, so that the magnets 123 can be used to fixedly attract an electronic product. The wireless charger 122 can be used to wirelessly charge to the electronic product. In alternative arrangements, the magnets 123 can be disposed on the panel board 13 or the front frame 113 of the supporting frame 11, which also can function to fixedly attract an electronic product.

### Third Embodiment

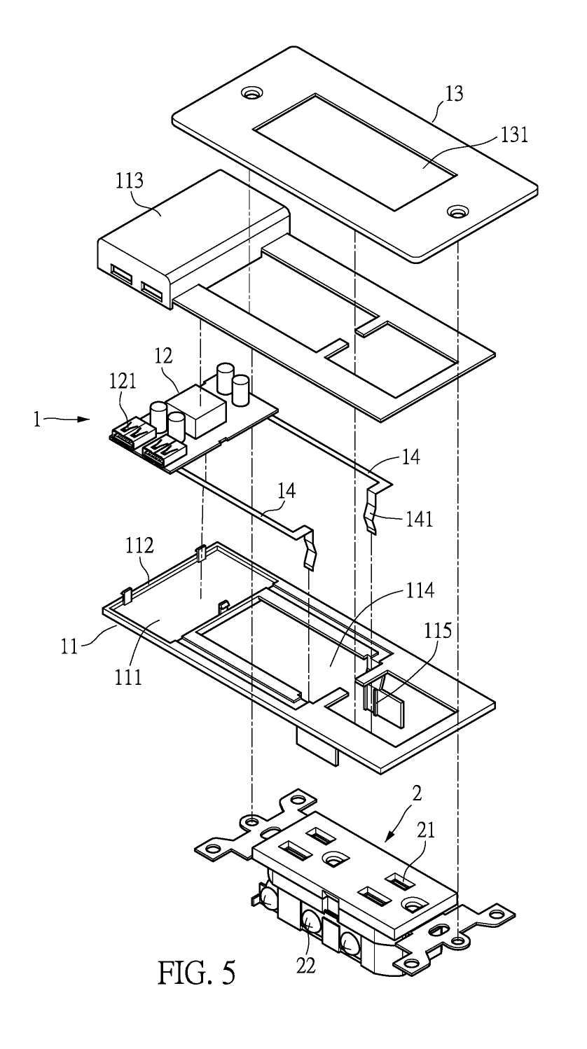

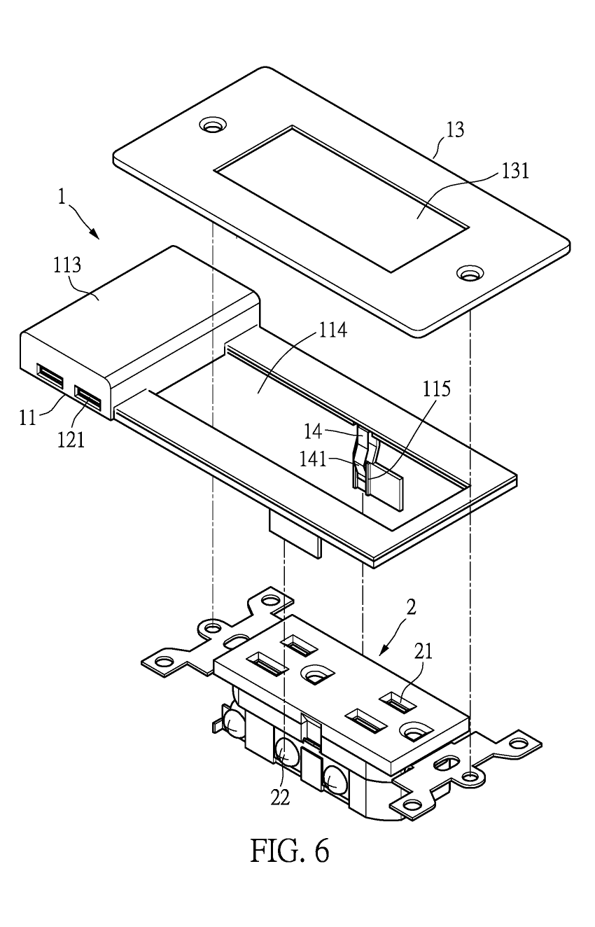

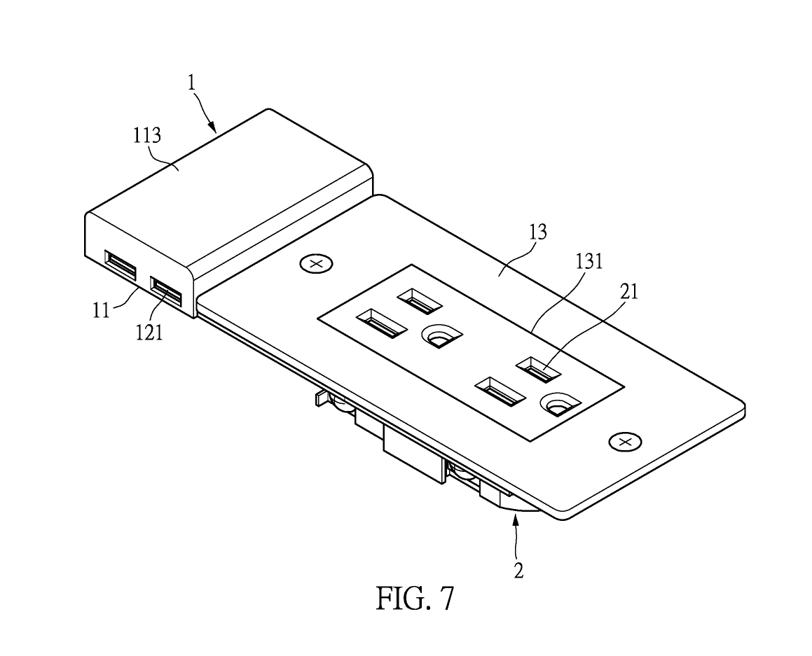

Reference is made to FIG. 5 to FIG. 7. In this embodiment, the electronic device 1 includes the supporting frame 11, the circuit unit 12 and the panel board 13. The structure of this embodiment is similar to the above embodiment, and a difference is that, the electrical socket 2 has a different specification. Thus, the shape of the supporting frame 11 and the panel board 13 of the electronic device 1 are changed correspondingly. In other words, the first opening 114 of the supporting frame 11 and the second opening 131 of the panel board 13 are properly changed according to the shape of the electrical socket 2. As shown in this embodiment, the second opening 131 of the panel board 13 is matched with a contour of the electrical socket 2 and is square-shaped.

### Fourth Embodiment

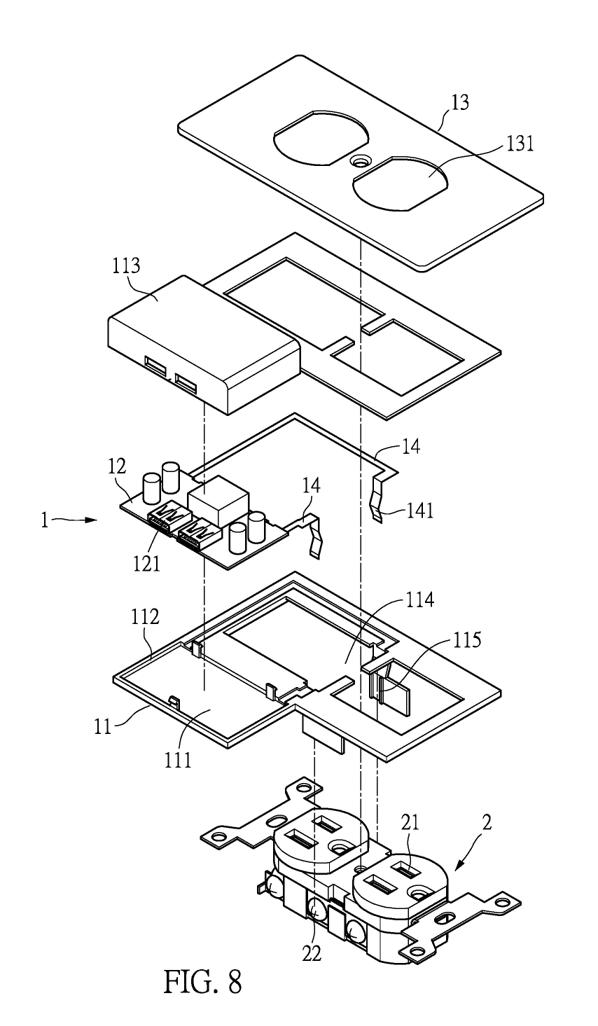

Reference is made to FIG. 8. In this embodiment, the electronic device 1 includes the supporting frame 11, the circuit unit 12 and the panel board 13. The structure of this embodiment is similar to the above embodiment, and a difference is that, the circuit unit 12 is disposed at a left side or a right side of the supporting frame 11.

### Fifth Embodiment

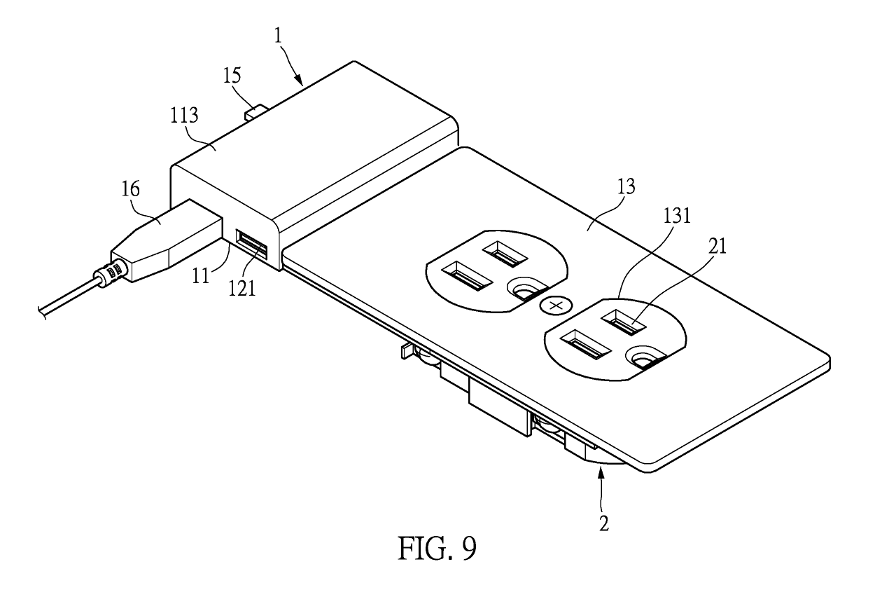

Reference is made to FIG. 9. In this embodiment, the electronic device 1 includes the supporting frame 11, the circuit unit 12 and the panel board 13. The structure of this embodiment is similar to the above embodiments, and a difference is that, the circuit unit 12 further has an adapter 15 which can be used to charge or transmit signals. In addition, the electrical connector 121 is connected with a cable 16 for charging or transmitting signals.

### Sixth Embodiment

Reference is made to 10. In this embodiment, the electronic device 1 includes the supporting frame 11, the circuit unit 12 and the panel board 13. The structure of this embodiment is substantially the same as the above embodiments. The difference is that, the supporting frame 11 is a one-piece integrated structure. The supporting frame 11 has a rear frame 112. The receiving space 111 and the first opening 114 are formed on the rear frame 112. The first opening 114 of the supporting frame 11 can be wrapped around the electrical socket 2. In other words, the electrical socket 2 is disposed in the first opening 114 of the supporting frame 11 in a matching way. The supporting frame 11 has two clipping tabs 115 which are extended from the rear frame 112. The two clipping tabs 115 are disposed at two sides of the first opening 114, and extend rearward beyond a rear side of the rear frame 112. The two clipping tabs 115 can be used to elastically clasp two sides of the electrical socket 2, so that the electronic device 1 can be stably combined with the electrical socket 2.

### Seventh & Eighth Embodiment

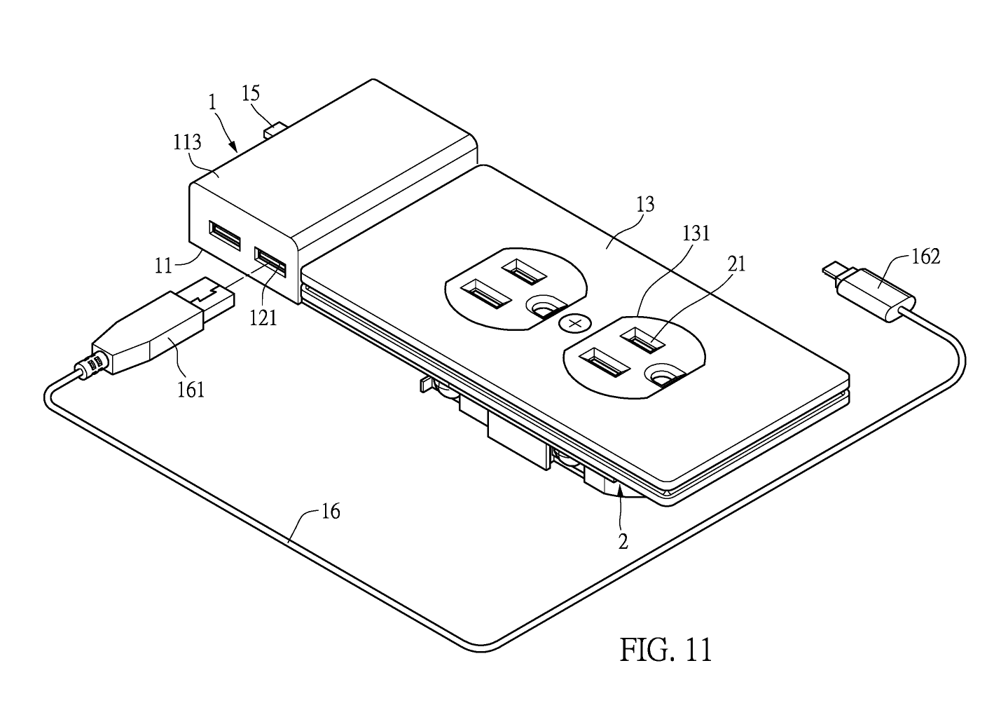

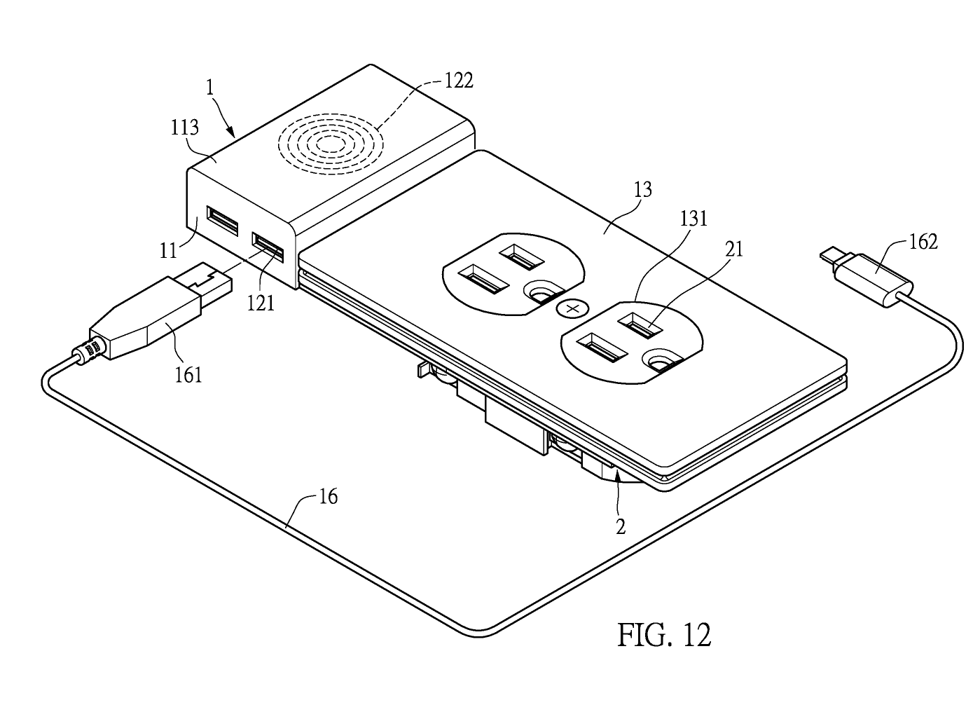

Reference is made to FIG. 11 and FIG. 12. In this embodiment, the electrical connector 121 is connected with a cable 16 which can be used to transmit power or signal. Two ends of the cable 16 have a first connector 161 and a second connector 162, respectively. The first connector 161 and the second connector 162 can be an electrical connector, such as a USB connector, an IEEE1394 connector, a HDMI connector, an AV terminal or a DC terminal . . . etc. One end of the cable 16 can be electrically connected to the electrical connector 121 by the first connector 161. The cable 16 is selectively wrapped around an edge of the panel board 13, so that the cable 16 can be properly fixed during unused time.

Moreover, as shown FIG. 12, in this embodiment, the circuit unit 12 includes a wireless charger 122 which can be used to wirelessly charge the electronic device by the wireless charger 122. The front frame 113 of the supporting frame 11 can further provide a supporting seat for allowing an electronic product disposed thereon.

The descriptions illustrated supra set forth simply the preferred embodiments of the present disclosure; however, the characteristics of the present disclosure are by no means restricted thereto. All changes, alterations or modifications conveniently considered by those skilled in the art are deemed to be encompassed within the scope of the present disclosure delineated by the following claims.

What is claimed is:

1. An electronic device for electrical socket, the electrical socket having a plurality of plug holes and two conductive parts, the two conductive parts disposed at two sides of the electrical socket, the electronic device comprising:
a supporting frame, having a receiving space formed therein, and a first opening, wherein the first opening is formed through a front side and a rear side of the supporting frame, the first opening of the supporting frame is fitted around a pheriphry of the electrical socket;
a circuit unit, disposed in the receiving space of the supporting frame;
two conductive elements, electrically connected to the circuit unit, each of the conductive elements having a contact portion, the contact portions of the two conductive elements arranged at two sides of the first opening of the supporting frame, wherein the contact portions are protruded to a rear side of the supporting frame, and the contact portions of the two conductive elements are contacted to the two conductive parts of the electrical socket, so that the circuit unit is electrically connected to the electrical socket; and
a panel board, having a second opening formed through a front side and a rear side of the panel board, the panel board covered on a front side of the supporting frame, the second opening of the panel board arranged corresponding to the plug holes of the electrical socket, so that the plug holes of the electrical socket are exposed exteriorly by the first opening of the supporting frame and the second opening of the panel board.

2. The electronic device for electrical socket as claimed in claim 1, wherein the supporting frame includes a rear frame and a front frame, and the rear frame is assembled with the front frame, wherein the receiving space is formed between the rear frame and the front frame.

3. The electronic device for electrical socket as claimed in claim 1, wherein the supporting frame has two clipping tabs arranged at two sides of the first opening, and the two clipping tabs are extended rearward and protruded to an rear side of the supporting frame, wherein the two contact portions of the conductive element are arranged at an inner side of the two clipping tabs, and the two clipping tabs are capable to clip two sides of the electrical socket.

4. The electronic device for electrical socket as claimed in claim 3, wherein the two contact portions of the conductive element are blade-shaped type.

5. The electronic device for electrical socket as claimed in claim 1, wherein the circuit unit has an electrical connector.

6. The electronic device for electrical socket as claimed in claim 1, wherein the circuit unit is a transformer, a nightlight, a wireless charger, a security light, a wireless controller, a wireless access point, a wireless module, a timer, an electricity leakage breaker, a cord winder, a sensor, a motion sensor or a battery.

7. The electronic device for electrical socket as claimed in claim 1, wherein the supporting frame is U-shaped or shaped in a frame structure.

8. The electronic device for electrical socket as claimed in claim 1, wherein the circuit unit is disposed at a left-half portion, a right-half portion, an upper-half portion or a lower-half portion of the supporting frame.

9. The electronic device for electrical socket as claimed in claim 1, wherein the supporting frame includes a rear frame and a front frame, and the rear frame is assembled with the front frame, wherein the receiving space is formed between the rear frame and the front frame, and the supporting frame has two clipping tabs arranged at two sides of the first opening, the two clipping tabs extended rearward and protruded to a rear side of the supporting frame, wherein the two contact portions of conductive element are arranged at an inner side of the two clipping tabs, the two clipping tabs are capable to clip two sides of the electrical socket.

10. The electronic device for electrical socket as claimed in claim 1, wherein the circuit unit has a plurality of magnets.
